(19) United States
(12) Patent Application Publication
(10) Pub. No.: US 2013/0173076 A1
(43) Pub. Date: Jul. 4, 2013

(54) Power Management System and Method Using Power Limiter

(71) Applicant: Yang Pan, Shanghai (CN)

(72) Inventor: Yang Pan, Shanghai (CN)

(21) Appl. No.: 13/342,113

(22) Filed: Jan. 2, 2012

(51) Int. Cl. G06F 1/28; G01R 21/00; G06F 19/00

(52) U.S. Cl. 700/292; 700/295; 702/58

(57) ABSTRACT

In one embodiment, electrical appliances in a household are connected to a power supply through power limiters that are further coupled to a controller. The power limiters include power sensors. Abnormal power consumption situations are detected by the power sensors. A communication unit coupled to the controller is triggered to communicate the abnormal situations to a personal computing and communication device of in a communication network. A user may send instructions to the controller to change operation modes of the appliances. In another embodiment, subsystems of an electrical appliance are connected to a power supply through power limiters.

### CROSS-REFERENCE TO RELATED APPLICATIONS

Not applicable

### BACKGROUND

1. Field of Invention

This invention relates to a power management system, specifically to a power management system of electrical appliances for reducing power consumptions.

2, Description of Prior Art

Standby power refers to the electrical power consumed by electronic devices or electrical appliances while they are switched off. Some such appliances offer remote controls and digital clocks features to a user, while other devices, such as power adapters for disconnected electronic devices, consume power without offering any features.

In the past standby power was largely a non-issue for users, electricity providers, manufacturers, and government regulators. Recently, awareness of the issue has grown because of increased adoption of home electronic devices and electrical appliances. Rechargeable batteries are used in many new devices. The standby power consumes typically up to 10% the electrical power usage of an average household.

However, it is difficult for a user to take actions to reduce such undesired power consumptions. A user only knows the total amount of power consumed based upon monthly electrical bill. It is desirable that system and method is provided to monitor individual device and appliance power consumption and to communicate any abnormality to the user. Therefore, actions can be taken by the user to reduce the power consumptions in the household.

### SUMMARY OF THE INVENTION

It is therefore an object of the present invention to provide a system and method for measuring and limiting power consumption of each of electrical appliances in a household by using of power limiters.

It is another object of the present invention to provide a system and method for measuring and limiting power consumption of each of subsystems of an electrical appliance by using of power limiters.

It is yet another object of the present invention to provide a system and method for communicating abnormal power consumption status of the appliances and the subsystems of the appliances to an external computing and communication device through a communication network and therefore actions can be taken remotely to reduce the power consumptions in the household.

In one embodiment, each of the electrical appliances is connected to a power supply through a programmable power limiter. The power limiter includes a power sensor. A controller controls operation of the power management system by setting power limit for the power limiters. The power limit may be determined based upon the appliance's operation mode. In a standby mode of an appliance, a much lower power limit is typically imposed to the power limiter. The controller acquires data from the power sensor regularly and analyzes the received data. Abnormality in power consumption for anyone of the appliances will be reported to a mobile communication device of the user or to an external server operated by an operator through a communication network.

The abnormality may be classified as an unusually high level of standby power (e.g., reaching the power limit of the power limiter) for an appliance. The abnormality may also be classified as a notable increase in the power consumption for the appliance under the same operation mode.

The user can review the power consumption status of the appliances and can decide to switch off completely one or more appliances by sending a control signal to the controller through the communication network.

In another embodiment, each of the subsystems of an electrical appliance is connected to a power supply through a power limiter. A controller monitors power consumption status of the subsystems in accordance with their operation modes. Abnormality of the subsystems will be reported through a communication network.

In one aspect, the status of the power consumptions of the appliances or the subsystems of the appliances may be stored in a file storage system connected to the controller. The user or a service person may read out the stored data through an ad hoc communication link, such as, for example, through radio frequency identification (RFID) type of devices.

The power limiters may be implemented based upon thermal feedback loops based on a microchip or a microstructure. The power limiters may be implemented as an AC power limiter or alternatively as a DC power limiter.

### BRIEF DESCRIPTION OF THE DRAWINGS

For a more complete understanding of the present invention and its various embodiments, and the advantages thereof, reference is now made to the following description taken in conjunction with the accompanying drawings.

FIG. 1 is a schematic diagram illustrating an exemplary power management system for an AC appliance.

FIG. 2 is a schematic diagram illustrating an exemplary power management system for a DC appliance.

FIG. 3 is a schematic diagram of functional blocks of an exemplary power management system for an AC appliance.

FIG. 4 is a schematic diagram of an exemplary household power management system including AC and DC appliances.

FIG. 5 is a schematic diagram of an exemplary power management system for an electrical appliance including multiple subsystems.

FIG. 6 is a schematic diagram of an exemplary AC power limiter based upon thermal feedback loop.

FIG. 7 is a schematic diagram of an exemplary DC power limiter based upon thermal feedback loop.

FIG. 8 is a schematic diagram of another exemplary DC power limiter based upon thermal feedback loop.

FIG. 9A is a schematic diagram illustrating an exemplary communication system for the exemplary power management system.

FIG. 9B is a schematic diagram illustrating an exemplary personal mobile computing and communication device displayed with an icon alerting the user about abnormality of power consumption of an electrical appliance in a household.

FIG. 9C is a schematic diagram of an exemplary user interface of the personal computing and communication device that lists power consumption status of electrical appliances in a household.

FIG. 10 is a schematic diagram illustrating an exemplary ad hoc communication link between an appliance and an external computing and communication apparatus.

FIG. 11 is a flowchart illustrating operation of the household power management system as shown in FIG. 4.

FIG. 12 is a flowchart illustrating operation of the power management system for an appliance as shown in FIG. 5.

### DETAILED DESCRIPTION

The present invention will now be described in detail with references to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps have not been described in detail in order not to unnecessarily obscure the present invention.

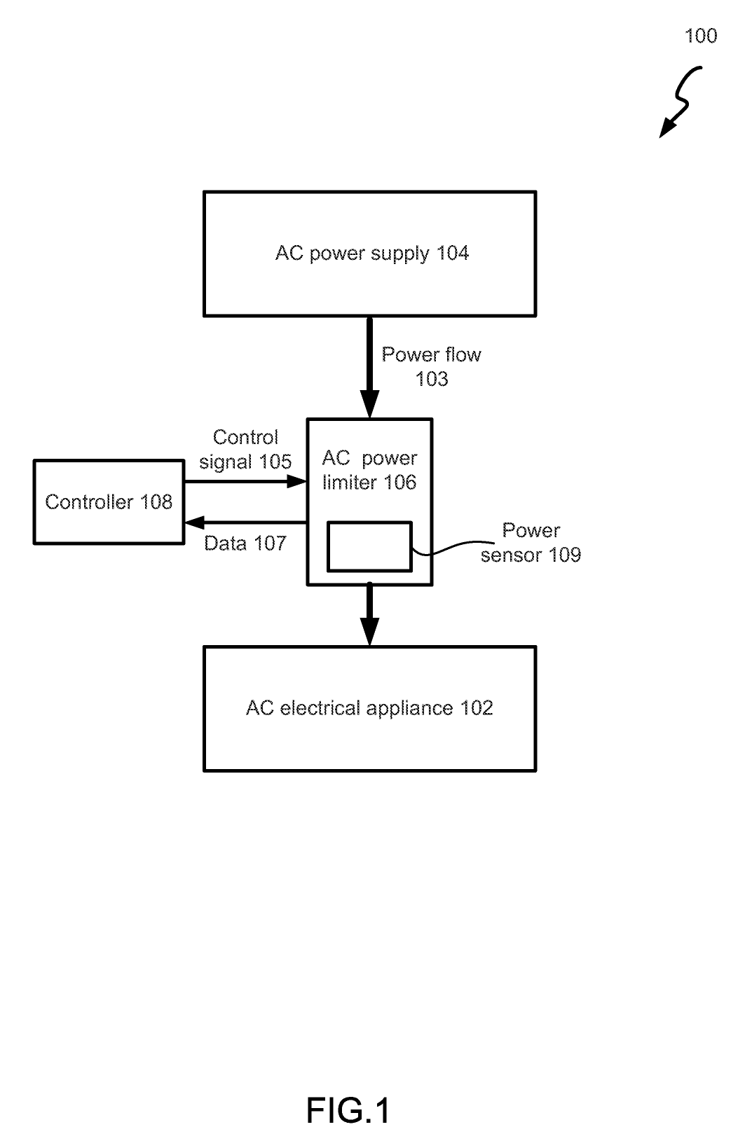

FIG. 1 is a schematic diagram illustrating an exemplary power management system for an AC appliance. System 100 comprises an AC appliance 102. Appliance 102 may include but is not limited to an air-conditioner, a heater, a refrigerator, an electrical fan, a television system, an audio system, an electrical lamp, a fax machine, a washing machine, a dish washer and an electrical cooker. Appliance 102 is connected to an AC power supply 104 through a power limiter 106. AC power supply 104 draws electrical power from a power grid or a sub-grid. Appliance 102 may receive its power through an outlet on a wall. Power limiter 106 is coupled to a controller 108 through a communication link. Controller 108 sends a control signal 105 to power limiter 106 and sets power limit for the power limiter 106. Power limiter 106 further includes a power sensor 109. Power sensor 109 measures the power flow 103 from AC power supply 104 to AC appliance 102. Power limiter sends measured data 107 to controller 108. In one aspect, the power consumption data is measured regularly by power sensor 109 and the measured data 107 is sent to the controller in accordance with a predetermined frequency. In another aspect, the measured data 107 is sent to the controller only if abnormality in power consumption is detected by power sensor 109 (e.g., the power drawn by AC appliance 102 reaches the power limit of power limiter 106).

In one aspect, controller 108 is a standalone device. Controller 108 may communicate with power limiter 106 either through a wired connection or through a wireless communication link. The wired connection may include an IEEE 1394 type of connector (FIREWIRE) or a Universal Serial Bus (USB) type of connector or any other type of connectors as known in the art. The wireless communication link may include but is not limited to Wi-Fi, Bluetooth, ZigBee and Near-Field-Communication (NFC) type of links. The wireless communication link may even include optical communication links comprising a visible light and an infrared light communication means.

In another aspect, controller 108 may be a part of AC appliance 102 or a part of power limiter 106, or even a part of AC power supply 104.

Power limiter 106 may be a part of AC appliance, a part of AC power supply or a standalone device in a power distribution path from AC power supply 104 to AC appliance 102.

The power limit of power limiter 106 is adjustable by controller 108. AC appliance 102 may be operated under various operation modes, such as, for example, under a mode for delivering desired functionalities or under a standby mode. Controller 108 sets the power limit for power limiter 106 according to the operation mode of appliance 102. In according with one implementation, power limiter 106 includes a switch (not shown in FIG. 1) that switches off power flow 103 completely to save powers.

Power limiter 106 provides a protection to AC appliance 102. Because electrical power drawn from power supply 104 is limited by power limiter 106, components of AC appliance 102 are protected against surge of power from power supply 104. The components are also protected against potential overheat as a result of overdrawn of power from power supply 104.

In another aspect, controller 108 receives power consumption data and analyzes trends of power consumption of AC appliance 102. The trends may be analyzed with regard to specific operation modes. For example, if a notable increase over a period of time or a sudden increase in the standby power of AC appliance 102 is detected, controller 108 may decide to report such an abnormality to a server or to a personal computing and communication device through a communication network. By closely monitoring the power consumption status of AC appliance 102, appropriate actions can be taken to prevent serious waste of power and also to eliminate safety concerns associated with malfunction of the electrical appliances.

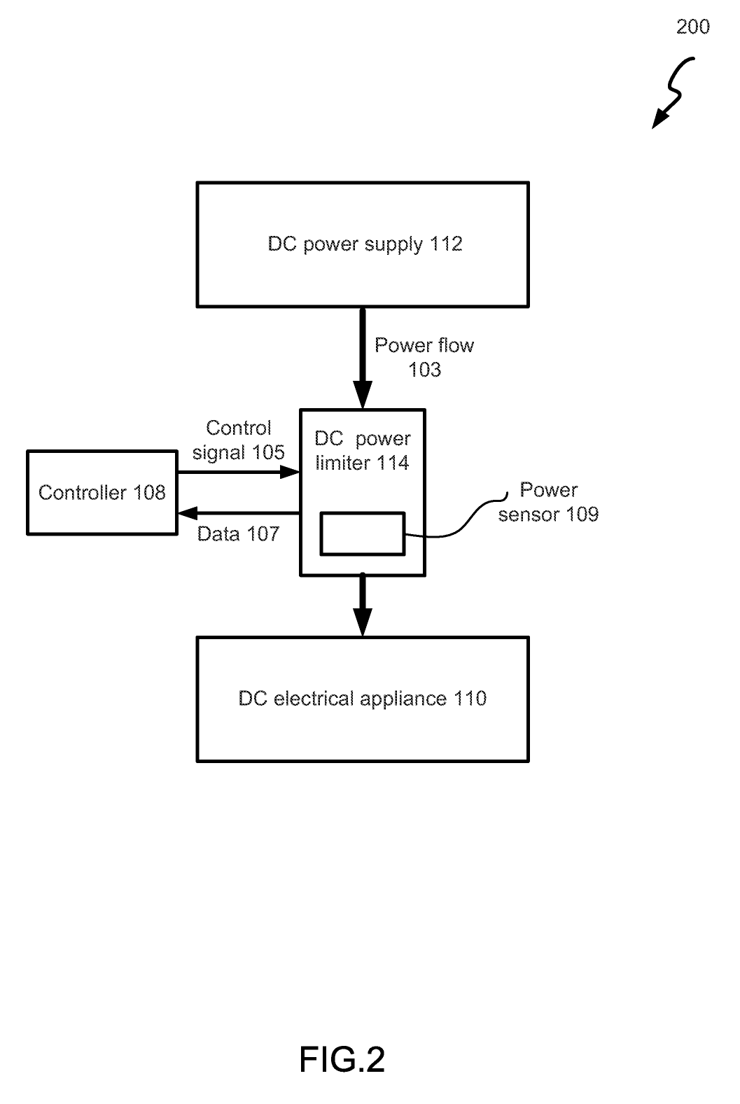

FIG. 2 is a schematic diagram illustrating an exemplary power management system for a DC appliance. System 200 includes a DC appliance 110. DC appliance 110 may include electronic devices that receive DC power for their operations. DC appliance 110 includes but is not limited to a computer and a light emitting diode (LED) lighting system. DC appliance 110 is connected to a DC power supply 112 through a DC power limiter 114. DC power supply 112 includes but is not limited to a power converted from an AC power, a power from a battery system, and a power from an alternative power generation source, such as, for example, a solar panel. DC power limiter 114 is controlled by controller 108. Controller 108 sends control signal 105 to DC power limiter 114 and receives power consumption data 107 measured by power sensor 109 from power limiter 114. Operation of system 200 is similar to that of system 100 other than the type of powers (e.g., DC versus AC).

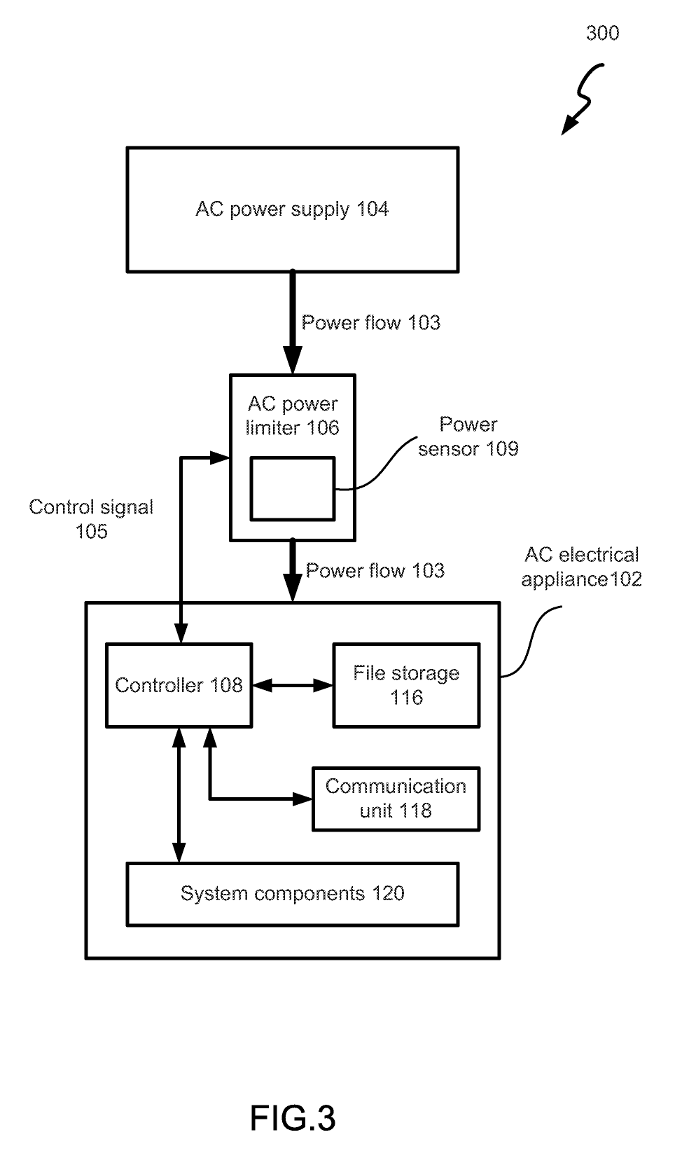

FIG. 3 is a schematic diagram of functional blocks of the exemplary power management system 100. The exemplary power management system 300 includes an AC electrical appliance 102 that is connected to AC power supply 104 through AC power limiter 106. In the embodiment, controller 108 is a part of AC appliance 102. A file storage unit 116 is coupled to controller 108. File storage unit 116 includes but is not limited to a FLASH memory or a RAM, a magnetic storage device such as a disk driver and an optic disk. Controller 108 receives power consumption status data provided by the power sensor 109 and stores the received data in file storage unit 116. In one aspect, file storage unit 116 may be a part of controller 108.

A communication unit 118 is further coupled to controller 108. Communication unit 118 receive an instruction from controller 118 and sends predetermined sets of data to a server or a personal computing and communication device through a communication network. In accordance with some embodiments, communication unit 118 conforms to various wireless communication protocols that include but are not limited to Wi-Fi (IEEE 802.11 and its extensions), Bluetooth (IEEE 802.15.1 and its extensions) and ZigBee (IEEE 802.15.4 and its extensions). Communication unit 118 may also include a gateway to a commercial communication network, such as, for example, to the Internet or to a telephony network. In accordance with another embodiment, communication unit 118 includes a protocol of Near-Field-Communication (NFC) or RFID. Data received by controller 108 can be stored in a non-volatile memory such as in a FLASH memory. A user or a service personal may read out the stored data by using a RFID reader nearby the appliance. An ad hoc communication link (e.g., Bluetooth, ZigBee or Wi-Fi) maybe established to read out stored data by a personal computing and communication devices of the user.

AC appliance 102 further includes system components 120 that are components receive power from power supply 104 and delivers designated functionalities of the appliance.

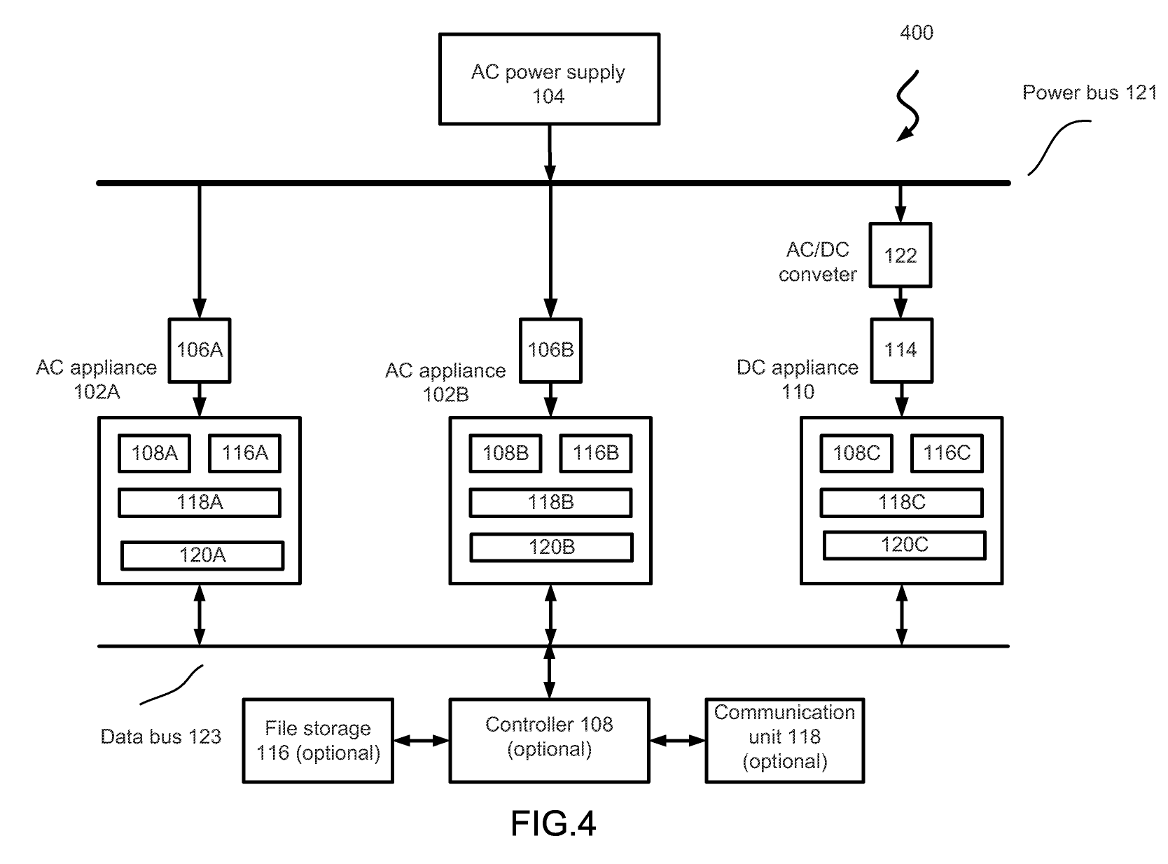

FIG. 4 is a schematic diagram of an exemplary household power management system 400 including AC appliances (102A and 102B) and DC appliances (110). In the embodiment, AC appliances 102A and 102B are connected to power supply 104 through power limiter 106A and 106B, respectively. The two appliances in FIG. 4 are illustrative and the power management system 400 may include more or less AC appliances. DC appliance 110 is connected to AC power supply 104 through an AC/DC converter 122 that converts AC power to DC power and DC power limiter 114. More or less DC appliances may be included in the system. The AC power is distributed to the appliances through a power bus 121.

In the embodiment, each of the appliances further includes a controller (108A, 108B and 108C), a file storage unit (116A, 116B and 116C) and a communication unit (118A, 118B and 118C). Each of the appliances also includes respective system components (120A, 120B and 120C) for delivering designated functionalities. Each of the power limiters is controlled by an associated controller, respectively.

In an alternative implementation, system 400 further comprises a centralized controller 108, a centralized storage unit 116 and a centralized communication unit 118. The data can be transmitted through a data bus 123 to each of the appliances. There are various derivative ways of implementing system 400 that fall into the scope of the present inventive concept. For example, in one implementation, centralized controller 108 may be used to replace controllers (108A and 108B and 108C) in each of the appliances. In an alternative implementation, some appliances may use its own controller and some other appliances may share the centralized controller. The file storage units (116A, 116B and 116C) may be dedicated for the appliance or may be shared by different appliances. Centralized storage unit 116 may also be shared by all or by some of the appliances. In one embodiment, only one communication unit 118 is used for system 400. In other embodiment, some of the appliances may include its own communication unit.

In one embodiment, controller 108 sends control signals to each of the power limiters and sets its power limit according to its operation mode. Power consumption status is measured by power sensors in the power limiters. Collected data is sent to the controller 108 for further analyzing. If any abnormality is detected by controller 108, communication unit 118 is instructed to send a report to an external server or to a personal computing and communication device of a user through a communication network. The received data may be stored in file storage unit 116.

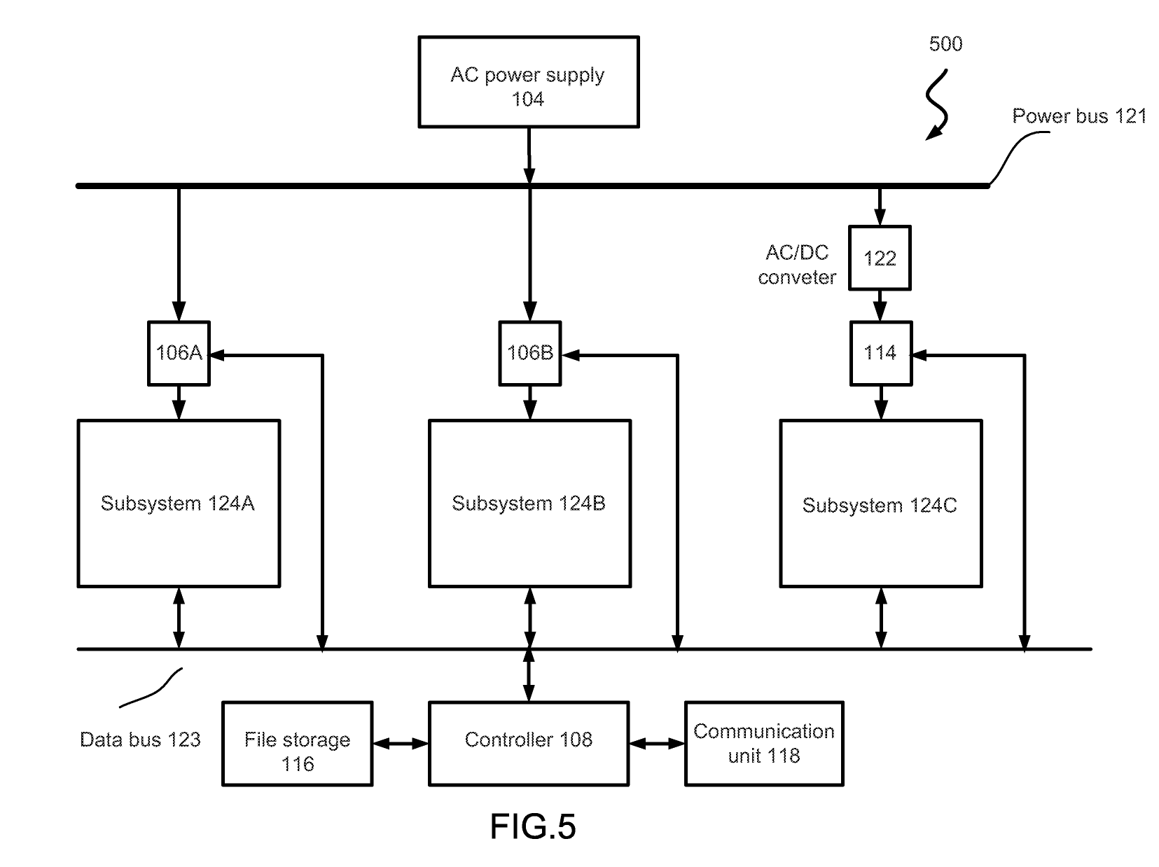

FIG. 5 is a schematic diagram of an exemplary power management system 500 for an electrical appliance including multiple subsystems. Subsystems 124A and 124B receive AC power from power supply 104 through power limiter 106A and 106B, respectively. Subsystem 124C receives DC power from AC/DC converter 122 that converts AC power from power supply 104 to DC form. DC power limiter 114 is placed in between Subsystem 124C and the AC/DC converter 122 to limit the power drawn by subsystem 124C. AC power from power supply 104 is distributed to the subsystems through power bus 121.

In the embodiment, system 500 (e.g., the electrical appliance) includes a controller 108, a file storage unit 116 and a communication unit 118. The use of storage unit 116 is optional and is not essential for the operation of the system. It should not limit the scope of the present inventive concept. Some of or all of subsystems may include optionally local controllers and/or file storage units. After system 500 is switched on, controller 108 sets a power limit for each of the power limiters according to an operation mode of each of the subsystems. A power sensor in each of the power limiters measures the power consumption and sends the collected data to controller 108 for further analyzing. The collected data may be stored in file storage unit 116. If an abnormality is detected, such as, for example, an abnormally high standby power for anyone of the subsystem is measured by the power sensor, controller 108 will trigger communication unit 118 to send out an alert through a communication network. In one aspect, the report may be delivered as an icon in a mobile computing and communication device coupled to the communication network to alert the user the abnormal status of the power consumption of an appliance or a subsystem of the appliance. The user reviews the report by open up the icon. The user may decide to send a control signal to controller 108 through the communication network to change the operation mode of the appliance (e.g., switch off the appliance completely). The user may also send a service request a service operator. The user may include the abnormal power consumption data in the request to the service operator.

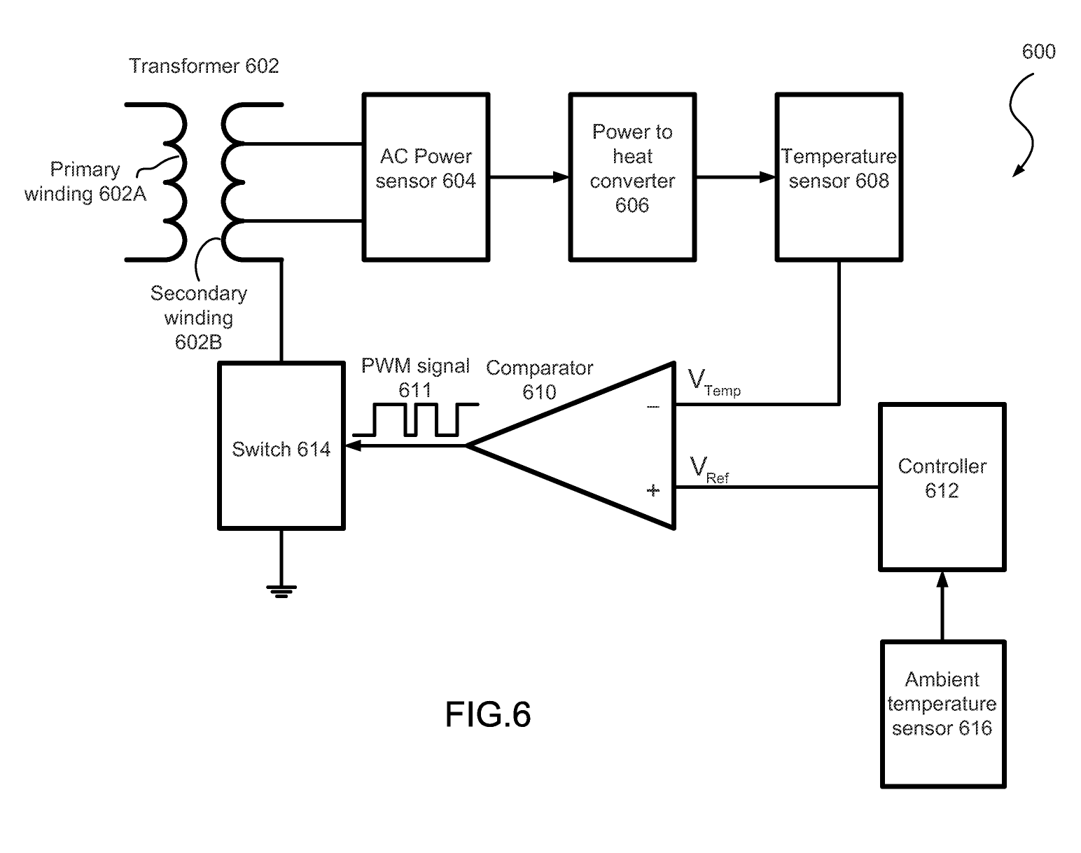

FIG. 6 is an exemplary power limiter implemented in AC power domain based upon an integrated circuit for measurements of thermal signals comprising a thermal feedback loop.

Such an implementation is known from an article by Pan (the present inventor) and Huijsing in Electronic Letters 24 (1988), 542-543. This circuit is theoretically appropriate for measuring physical quantities such as speed of flow, pressure, IR-radiation, or effective value of electrical voltage or current (RMS), the influence of the quantity grated integrated circuit (chip) to its environment being determined in these cases. In these measurements, a signal conversion takes place twice: from physical (speed of flow, pressure, IR-radiation or RMS value) to the thermal domain, and from the thermal to the electrical domain.

This known semiconductor circuit theoretically consists of a heating element, integrated in the circuit, and a temperature sensor. The power dissipated in the heating element is measured with the help of an integrated amplifier unit, an amplifier with a positive feedback loop being used, because of which the temperature oscillates around a constant value with small amplitude. In the known circuit the temperature will oscillate in a natural way because of the existence of a finite transfer time of the heating element and the temperature sensor with a high amplifier-factor.

FIG. 6 shows a novel implementation of the thermal feedback principle as mentioned above to AC power limiter 600. AC power limiter 600 comprises a transformer 602 including primary winding 602A and secondary winding 602B. Transformer 602 converts AC power with high amplitude in primary winding 602A to AC power with low amplitude in secondary winding 602B while maintaining the power almost constant. AC Power sensor 604 coupled to secondary winding 602B receives a portion of AC power proportionally. Power sensor 604 may further comprise a current sensor and/or a voltage sensor. The received AC power is further coupled to power to heat converter 606 that may include a heating element. The heating element may be a heating resistor in an exemplary case. The heating element may also be an active component. Power to heat converter 606 (heating element) may be a part of an integrated circuit or a chip. According to a different implementation, a rectifier (not shown in FIG. 6) may be used to convert the AC power into DC power before it is used to heat the heating element.

Temperature sensor 608 in the same integrated circuit is used to measure the temperature of the integrated circuit (chip). According to one implementation of the present invention, the heating element and temperature sensor may be placed in a microstructure such as a membrane or a cantilever beam, manufactured by a micromachining technology.

Output of temperature sensor 608 is coupled to one input of comparator 610. Reference generated by controller 612 is coupled to another input of comparator 610. Output of comparator 610, which is a Pulse-Width Modulation (PWM) signal, is coupled to switch 614 that is connected to secondary winding 602B of transformer 602 to form a positive feedback loop. Switch 614 may be implemented in various forms as known in the art. Switch 614 maybe a power Metal Oxide Semiconductor Field Effect Transistor (MOSFET) according to an implementation. Switch 614 may be a bipolar transistor according to another implementation. Switch 614 may even be a Light Emitting Diode (LED) and a photo detector. The output of comparator 610 may be used to drive the LED to emit light that will be detected by the photo detector. As soon as the measured temperature by temperature sensor 608 exceeds a predetermined value, set by the reference, the output of the comparator switches off switch 614. As a result, power sensor 604 receives no power from secondary winding 602B and the output of temperature sensor 608 starts to drop. As soon as the output is below the reference, the output of comparator 610 switches on switch 614 and therefore secondary winding 602B. The temperature of the chip or the microstructure will oscillate around a small value. The output power of secondary winding 602B will remain as a constant in a sine wave form modulated by the PWM signals. The output power of transformer 602 is limited by the duty cycle of the PWM signal. The output power may be delivered to electrical appliance 102.

The maximum output power of transformer 602 is determined by the reference that sets a level of temperature that the chip or the microstructure will oscillate around. To sustain a higher temperature, the power sensor will need to draw more power from the secondary winding 602B. The reference is determined by controller 612. Controller 612 may be the same as controller 108. Controller 612 may be a different controller. Controller 612 may set different power limit for power limiter 600 according to different operation modes of appliance 102.

It should be noted that the temperature level of the microstructure or the chip also depends on ambient temperature. At a lower ambient temperature, it requires more power to heat the heating element to maintain the temperature to oscillate around the predetermined level. At a higher ambient temperature, less power is required. In one aspect of the present invention, an ambient temperature sensor 616 is used to measure the ambient temperature. The measurement results are sent to controller 612. Controller 612 determines the reference based upon not only the operation mode of appliance 102 but also the ambient temperature measured by temperature sensor 616. Temperature sensor 616 may be a sensor independent of the integrated circuit or the chip. Temperature sensor 616 may also be a part of the integrated circuit or the chip that will require an appropriate thermal isolation between temperature sensor 606 and temperature sensor 616. Such thermal isolation techniques are known in the art.

In an exemplary implementation, the power limiter may be construed by a Silicon-on-Insulator (SOI) chip. Temperature sensor 616 may be placed in an isolated silicon island that is thermally isolated from the other circuits by the insulator of the SOI wafer.

There may be different implementations of integration level of system 600. At a minimum level, 606 and 608 are integrated in a single chip or in a single microstructure. At a higher level, 610 may also be integrated (e.g. 606, 608 and 610 in a single chip). At even higher levels, 612 and 614 may also be integrated (e.g. 606, 608, 610, 612 and 614 in a single chip). At still higher level, 616 may also be integrated (e.g. 606, 608, 610, 612, 614 and 616 in a single chip). All such variations shall fall within scope of inventive concepts of the present invention.

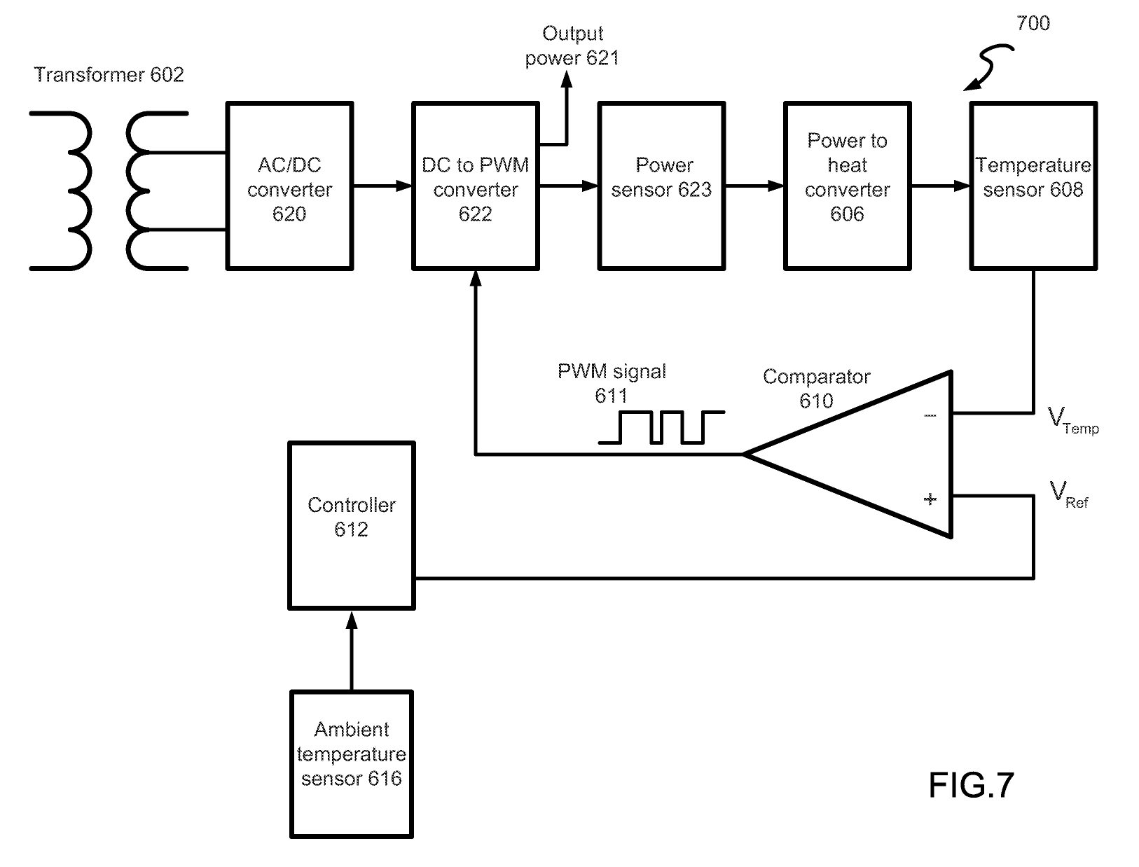

FIG. 7 shows an exemplary power limiter implemented in DC power domain with AC power source. System 700 comprises AC/DC converter 620 that converts output power of transformer 602 from AC form into DC form. Block 622 modulates the DC power by PWM signal 311. Power sensor 623 is coupled to Block 622 to draw a portion of power proportionally. Block 622 delivers output power 621 in PWM form. The power received by power sensor 623 is coupled to power to heat converter (heating element) 606. Temperature sensor 608 measures temperature of the microstructure (chip) that includes the heating element. Comparator 610 takes one input from the output of temperature sensor 608 and takes another input from a reference generated from controller 612. Output of comparator 610 in PWM form (611) is coupled to block 622 to modulate the DC power. The temperature of the chip will oscillate around a small value set by the reference. Block 622 converts output of AC/DC converter 620 into the power in PWM form. The output power of block 622 is therefore determined by duty cycle of the PWM signal while the amplitude is kept constant. The output power of block 622 may be further processed into DC and/or AC powers before it is delivered to appliances.

Controller 612 is coupled to ambient temperature sensor 616. Functionalities of 616 are similar to the ones that have been described previously in the AC power limiter session.

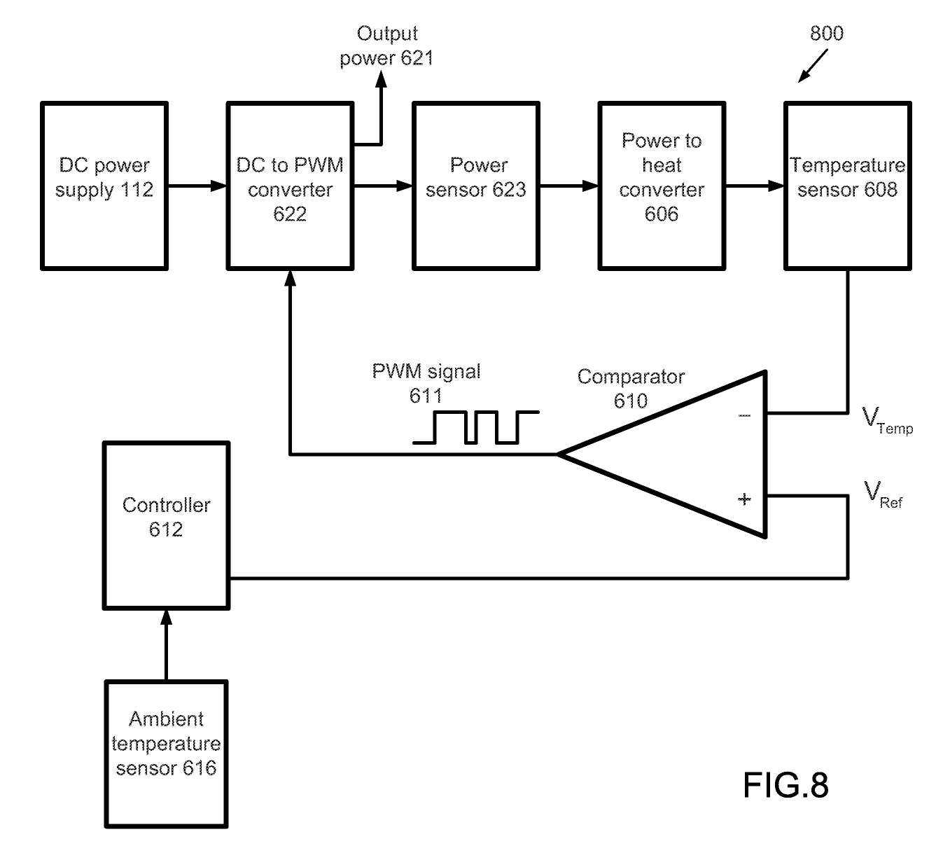

FIG. 8 shows an exemplary power limiter implemented in DC power domain with DC power source 112. Power limiter 800 is the same as power limiter 700 except that transformer 602 and AC/DC converter 620 are replaced by the DC power supply 112.

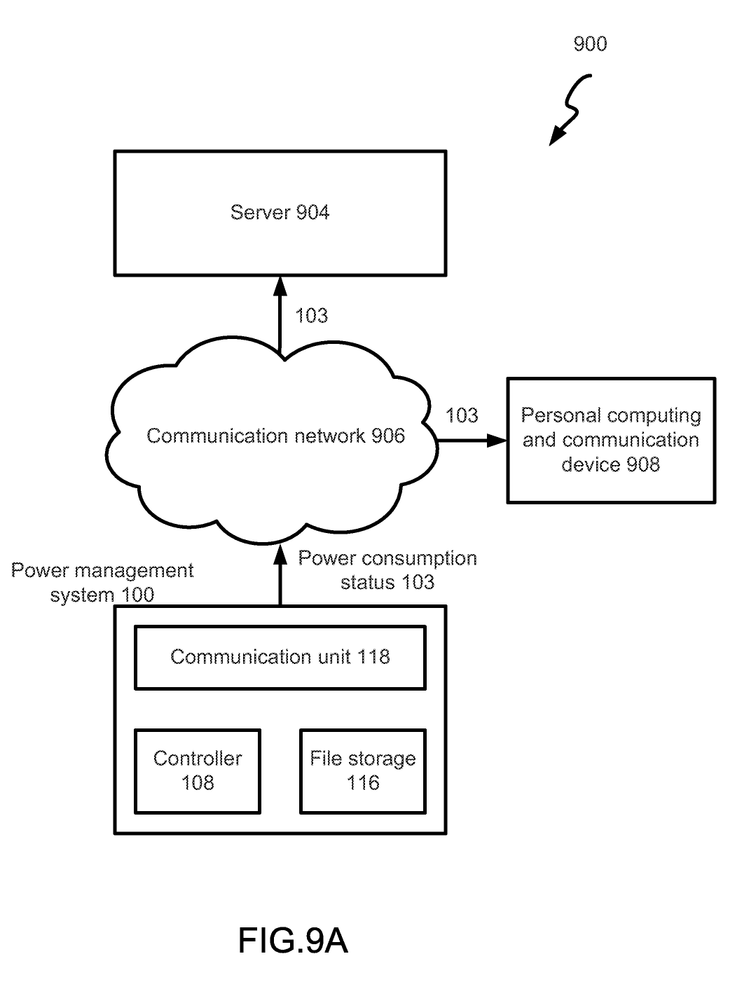

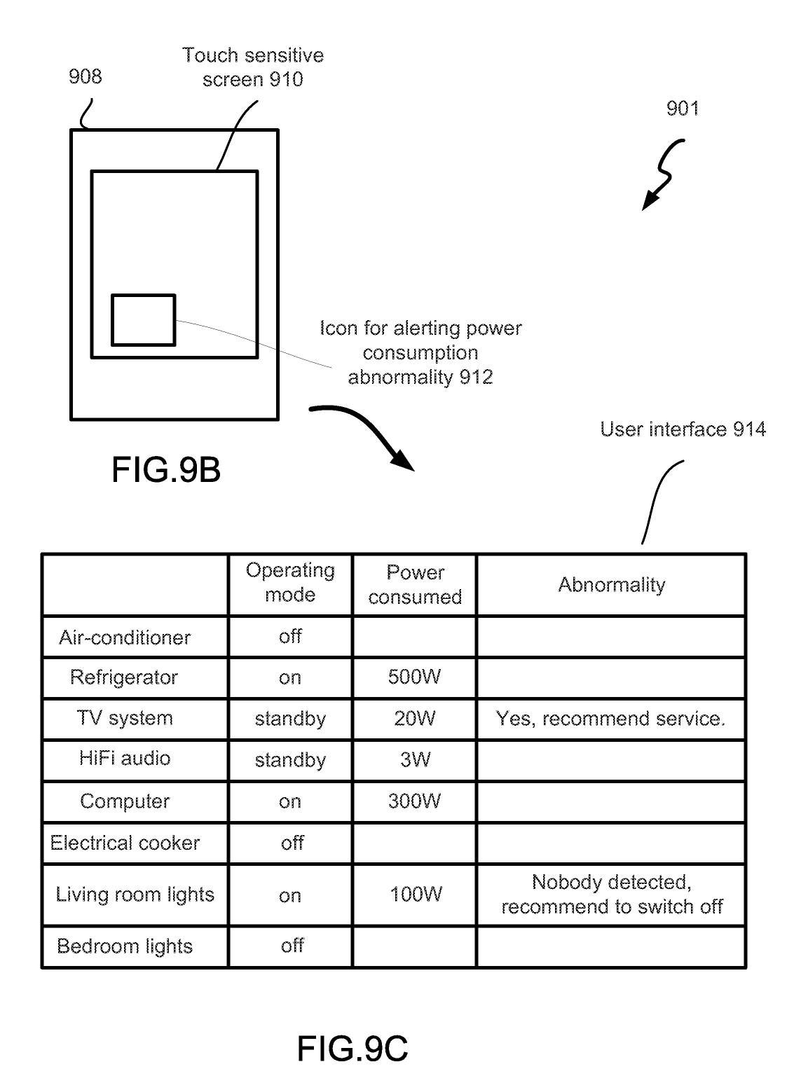

FIG. 9A is a schematic diagram illustrating an exemplary communication system for the exemplary power management system. Communication system 900 includes power management system 100 that is connected to a server 904 through a communication network 904. Power management system 100 further includes controller 108, file storage unit 116 and communication unit 118. Controller 108 receives data from power sensors 109 and sends power consumption status data to server 904 through the communication network 906. In one embodiment, communication network 906 is the Internet. In another embodiment, communication network 906 is a telephony network. Communication unit 118 may be coupled to network 906 directly. Communication unit 118 may also be coupled to the network through a network gateway (not shown in FIG. 9A). A personal computing and communication device 908 may be coupled to communication network 906. Device 908 includes but is not limited to a mobile phone, a tablet computer, a laptop computer, a desktop computer, a PDA, a handheld media player, a game console and a remote control device. A user may access to power consumption status of the appliances in a household in real time by using of system 900. The user may also change operation modes of the appliances by sending control signals through device 908, network 906 and communication unit 118 to controller 108. The user may switch on or off selected appliances. The user may switch off appliances in standby mode completely. The user may even send service request to a service operator through communication network 906. The service request may include power consumption status of the appliances showing abnormalities.

FIG. 9B is a schematic diagram illustrating that an alerting icon 912 may be displayed on a display 910 of the exemplary personal computing and communication device 908. In one aspect, display 910 is a touch sensitive screen. Icon 912 is displayed in response to detected power consumption abnormality by controller 108 (e.g., an abnormally high standby power for an appliance is detected.). It should be noted that displaying icon 910 is exemplary and is for illustration only. The user can be alerted by any other means, such as, for example, through a Short Message Service (SMS), a Multimedia Message Service (MMS) or through an email, or even through a voice message. It should be further noted that displaying the icon may be accompanied by sound or by other means of animations to attract attention of the user. For example, the displayed icon 910 may be vibrated. The size of icon 910 may be enlarged or be reduced. All such variations fall into the scope of the present inventive concept.

In accordance with another aspect, the personal device 908 may always display an icon for power consumption status of the appliances in the household. The status may be updated regularly. The user can always access the data by selecting the icon. A user interface will be displayed to guide the user to review the data.

FIG. 9C shows an exemplary user interface (UI) 914. Operation modes for a list of appliances are illustrated in a table form. An appliance may be labeled as “on”, “off” or “standby”. Power consumptions of the appliances are also included in the table. Abnormalities are indicated. In the exemplary case, a TV system is consuming an unusually high standby power. An action for service is recommended to the user. The user may decide to change the operation mode of the TV system to “off” from “standby” to save power. The user may also indentify through UI 914 the appliances that do not need to be in an “on” state. In the exemplary case, lights in the living room can be switched off remotely by the user through his or her interacting with UI 914. Control signals associated with changing of one or more appliances can be transmitted from personal device 908 to controller 108 through communication network 906.

UI 914 as shown in FIG. 9C is for a purpose of illustration only. UI may be designed in many different manners as known in the art. In one embodiment, UI may be construed in a hierarchical manner and the user may access to required data guided in a step by step manner through the user interface. In another embodiment, each of the appliances may be listed as a representative icon. The user may access to operation mode, power consumption and recommended actions by selecting the representative icon. The representative icons may be designed in an intuitive manner that can be easily recognized by the user to be associated with an electrical appliance. For example, a symbol of refrigerator may be used to represent the refrigerator in the household. The icon representing an appliance with abnormal power consumption status may be colored to attract the user's attention. All such variations will fall into the scope of the present invention.

In another aspect, UI 914 may provide additional functionalities that include but are not limited to 1) plot a trend chart for a predetermined period of time of power consumption of an appliance in one of its operation modes; 2) analyze the trend chart based upon a statistic process control (SPC); and 3) alert the user abnormal trend based upon predetermined rules. The predetermined rules may include detecting out of control events and detecting “trend up” or “trend down” events. The user may decide to take appropriate actions according to the results from analyzing the trend charts.

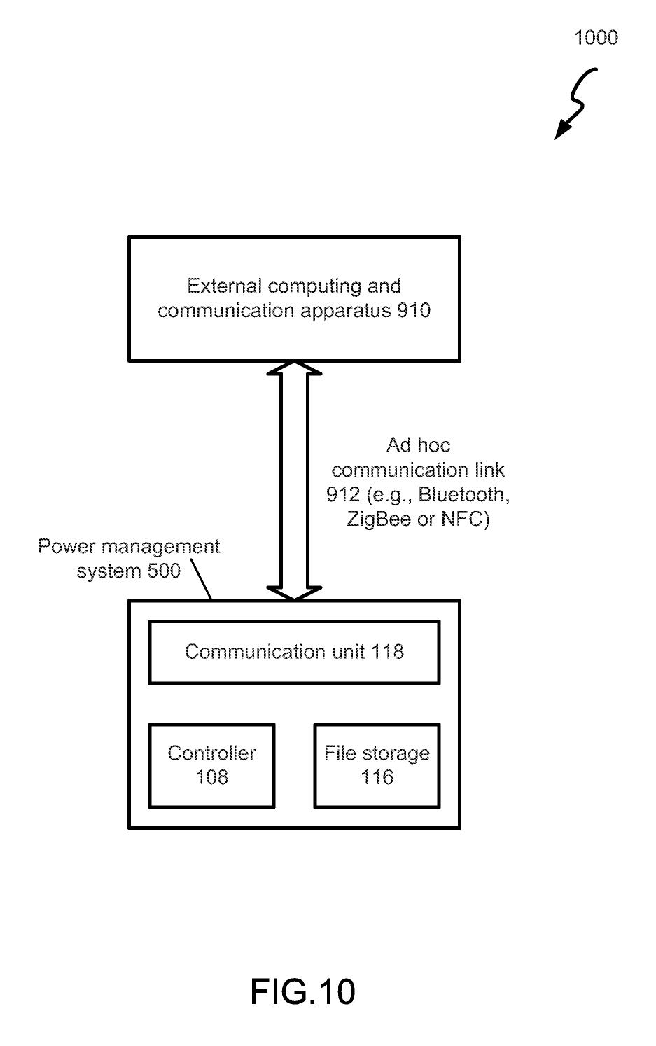

FIG. 10 is a schematic diagram illustrating an exemplary ad hoc communication link between an appliance and an external computing and communication apparatus. An exemplary system 1000 includes the power management system 500 as illustrated in FIG. 5 for an electrical appliance. System 500 is coupled to an external computing and communication apparatus 910 through an ad hoc communication link 912. Ad hoc communication link 912 includes but is not limited to a Bluetooth type of connection (IEEE 802.15.1), a ZigBee type of connection (IEEE 802.15.4 and its extensions) and a Wi-Fi type of connection (IEEE 802.11 and its extensions). Ad hoc communication link 912 may further include a NFC type of connection, such as, for example, a RFID type of connection. Collected data about power consumption status of the subsystems may be stored in a FLASH memory. External computing and communication apparatus 910 including a RFID reader may be used to readout data stored in the FLASH memory. The data may be analyzed to determine if anyone of subsystems is malfunctioning with regard to the power consumptions.

It should be noted that communication network 906 may be employed not only to transmit power consumption data of the appliances in the household but also power consumption data of their subsystems. The data can be used by the service operator to diagnose and to determine subsystems that cause the abnormal power consumption problems.

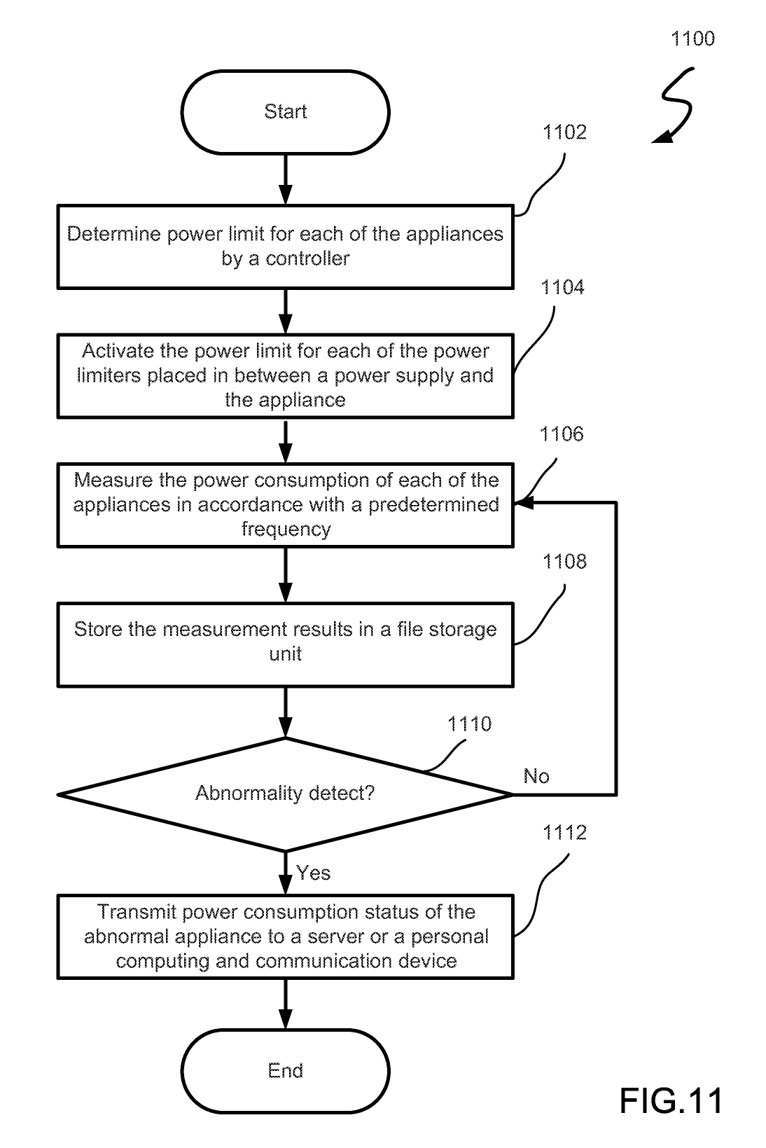

FIG. 11 is a flowchart illustrating operation of the household power management system of FIG. 4. Process 1100 begins with step 1102 that a power limit for each of the power limiters is determined by controller 108. The power limit may be determined by the centralized controller 108. The power limit may also be determined by local controller 108A, 108B or 108C in each of the appliances. The power limit is determined based upon an operation mode of each of the appliances. Controller 108 sends a control signal to each of the power limiters to activate the power limitation in step 1104. The control signal may include a reference for one of the inputs of the comparator 610 if the power limiter is construed upon the thermal feedback loop as illustrated in FIGS.6-8. The power limiters are placed in between the appliance and the power supply. As shown in FIGS.1-3 and 6-8, power sensors are used in the power limiters. Power consumptions of each of the appliances in the household are measured by power sensors in the power limiters in step 1106. The measurement results may be stored in the file storage unit 116 or in units 116A, 116B and 116C in step 1108. Step 1108 is optional and is not essential for the operation of system 400 and should not limit the scope of the present inventive concept. However, storing power consumption data in the file storage unit will help to generate the trend charts of the power consumptions and help to diagnose power consumption issues as discussed previously. Controller 108 receives power consumption data generated by the power sensors and makes a decision in decision 1110 if abnormality has been detected. If the decision indicates that no abnormality has been detected, controller 108 will continue to monitor power consumption status of each of the appliances until an abnormality is detected. If the decision indicates that an abnormality has indeed been detected, controller 108 sends a control signal to communication unit 118 and transmits the power consumption data of the abnormal appliance to an external server 904 or a personal computing and communication device 908 through communication network 906 in step 1112.

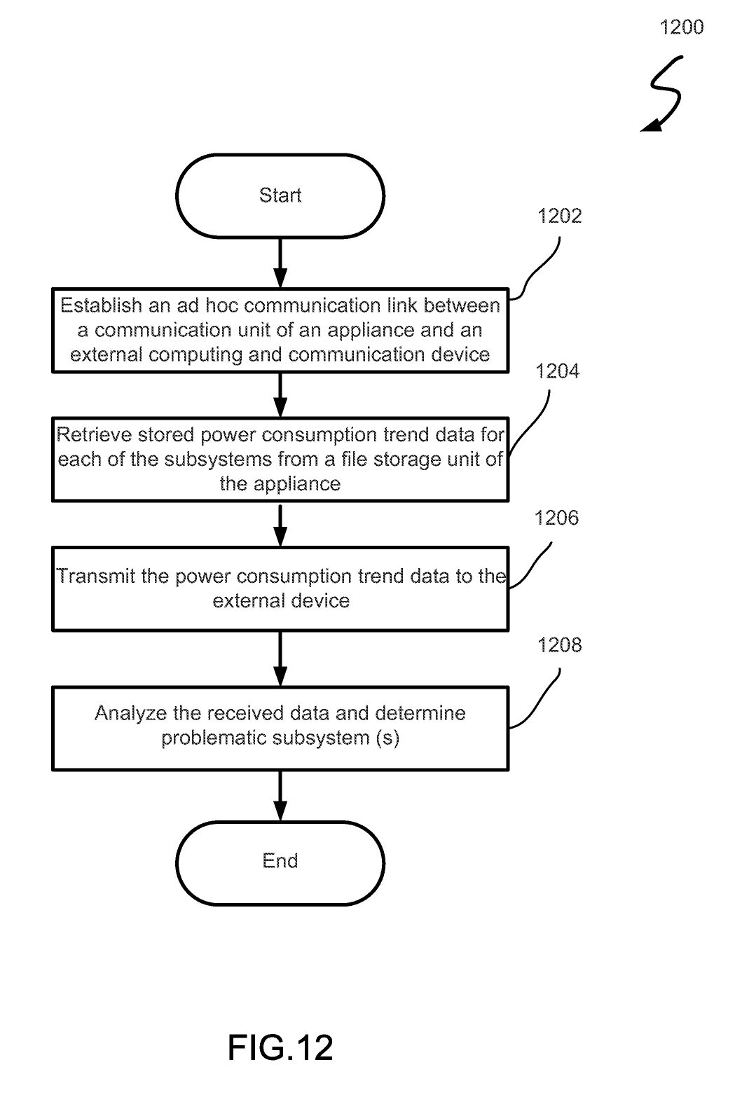

FIG. 12 is a flowchart illustrating operation of the power management system for an appliance as shown in FIG. 5. Process 1200 begins with step 1202 that an ad hoc communication link 912 is established between a communication unit 118 of an electrical appliance 102 and an external computing and communication apparatus 910. Electrical appliance 102 includes power management system 500 as shown in FIG. 5. Ad hoc communication link 912 includes but is not limited to a Bluetooth type connection, a ZigBee type of connection, a Wi-Fi type of connection and a NFC type of connection. Ad hoc communication link 912 may even include an optical communication link using of a visible light beam or an infrared light communication means. After the communication link 912 is established, controller 108 retrieves power consumption trend data stored in file storage unit 116 in step 1204. The retrieved data are transmitted to the external computing and communication device 910 through ad hoc communication link 912 in step 1206. The data are received by the device 910 and are analyzed by the device in step 1208 to determine if anyone of the subsystems of the appliance is operating abnormally in anyone of its operation modes.

While the invention has been disclosed with respect to a limited number of embodiments, numerous modifications and variations will be appreciated by those skilled in the art. Additionally, although the invention has been described particularly with respect to a power management system for a household, it should be understood that the inventive concepts disclosed herein are also generally applicable to other power consumption units including commercial units such as shopping malls, factories and schools or any of commercial or residential establishments. The present inventive concepts are applicable to any implementation of power limiters. It is intended that all such variations and modifications fall within the scope of the following claims:

1. A power management system comprising:
(a) a power source;
(b) a plurality of electrical appliances, wherein each of the appliances is connected to the power source through a power limiter, wherein said power limiter further comprising a power sensor;
(c) a communication unit;
(d) a controller that is coupled to the power limiters and to the communication unit; and
(e) a means of detecting and communicating an abnormal power consumption status of anyone of said appliances.

2. The system as recited in claim 1, wherein said system further comprises a file storage system pertaining to storing data related to power consumptions of said appliances.

3. The system as recited in claim 1, wherein said controller further comprises a means of setting a power limit for a power limiter in accordance with an operation mode of an appliance that the power limiter is connected to, wherein said operation mode includes at least “on” and “standby”.

4. The system as recited in claim 1, wherein said abnormal power consumption status further comprises an event that power consumption of anyone of said appliances reaches the power limit set by the controller.

5. The system as recited in claim 1, wherein said controller further comprises a software program for analyzing trends of power consumptions of said appliances over a predetermined period of time and for detecting abnormal power consumption status associated with the trends.

6. The system as recited in claim 1, wherein said appliances further comprises a first group of appliances that receive AC power and a second group of appliances that receive DC power.

7. The system as recited in claim 1, wherein said abnormal power consumption status is transmitted to a server or to a personal computing and communication device by the communication unit through a communication network.

8. The system as recited in claim 7, wherein said personal computing and communication device further comprises a user interface, wherein said user interface further comprises;
(a) a means of displaying power consumption status of said appliances;
(b) a means of displaying an alert about the abnormal power consumption status; and
(c) a means of receiving and sending a user's instructions to change operation modes of said appliances.

9. The system as recited in claim 1, wherein said communication unit conforms to one of the following communication protocols:
(a) the Internet;
(b) Bluetooth;
(c) ZigBee;
(d) Wi-Fi;
(e) Near Field Communication,
(f) a visible light communication; and
(g) an infrared light communication.

10. The system as recited in claim 1, wherein said controller further comprises a means of changing an operation mode of one of the appliances after receiving an instruction from the communication unit, wherein said instruction is initiated by a user through a computing and communication device.

11. A power management system for an electrical appliance comprising:
(a) a plurality of subsystems, wherein each of the subsystems is connected to a power source through a power limiter;
(b) a communication unit;
(c) a controller pertaining to controlling at least operations of the power limiters and the communication unit; and
(d) a means of detecting and communicating an abnormal power consumption status from anyone of said subsystems.

12. The system as recited in claim 11, wherein said appliance further comprises a file storage system pertaining to storing at least data related to power consumptions of said subsystems.

13. The system as recited in claim 11, wherein said controller further comprises a means of setting a power limit for a power limiter.

14. The system as recited in claim 11, wherein said abnormal power consumption status further comprises an event that power consumption of anyone of the subsystems reaches the power limit set by the controller.

15. The system as recited in claim 11, wherein said controller further comprises a software program for analyzing trends of power consumptions of the subsystems over a predetermined period of time and for detecting the abnormal power consumption status associated with the trends.

16. The system as recited in claim 11, wherein said communication unit transmits said abnormal power consumption status to an external computing and communication device through a communication link, wherein said communication link further comprises one of the following types:
(a) the Internet;
(b) Bluetooth;
(c) ZigBee;
(d) Wi-Fi;
(e) Near Field Communication;
(f) a visible light communication; and
(g) an infrared light communication.

17. The system as recited in claim 11, wherein said power limiter is constructed based upon a thermal feedback loop, wherein said thermal feedback loop further comprises a power sensor, a temperature sensor and a comparator.

18. A method of power management for an electrical system comprising a plurality of subsystems, the method comprising:
(a) connecting each of the subsystems to a power supply through a power limiter;
(b) setting power limit of the power limiters by a controller;
(c) detecting an event that power consumption of anyone of the subsystems reaches the power limit; and
(d) communicating the event to an external computing and communication device through a communication link.

19. The method as recited in claim 18, wherein said method further comprises storing data related power consumption trends of the subsystems in a file storage unit of the electrical system.

20. The method as recited in claim 19, wherein said method further comprising transmitting stored data to the external computing and communication device through an ad hoc communication link, wherein said ad hoc communication link further comprises a radio frequency identification (RFID) type of communication link.
